(19) United States
(12) Patent Application Publication
(10) Pub. No.: US 2026/0317893 A1
(43) Pub. Date: Oct. 15, 2026

(54) A method for manufacturing a patterned polymer film structure

(71) Applicant: Turun yliopisto, Turun yliopisto (FI)

(72) Inventors: Carita Kvarnström, Turun yliopisto (FI); Mikko Salomäki, Turun yliopisto (FI); Pia Damlin, Turun yliopisto (FI); Kari Loikas, Turun yliopisto (FI); Mauri Nauma, Turun yliopisto (FI); Rahul Yewale, Turun yliopisto (FI)

(21) Appl. No.: 19/101,266

(22) PCT Filed: Aug. 2, 2023
(86) PCT No.: PCT/FI2023/050451

§ 371 Date: Feb. 5, 2025

(30) Foreign Application Priority Data
Aug. 5, 2022 (FI) 20225704

(51) Int. Cl. C23C 16/04; H10K 71/12; H10K 85/10

(52) U.S. Cl. CPC C23C 16/04; H10K 85/1135; H10K 71/12

(57) ABSTRACT

The present invention relates to a method for manufacturing a patterned film on a substrate, the method comprising forming an oxidant layer on a substrate by applying a solution comprising an oxidant on the surface of the substrate by coating; drying the oxidant layer; applying an inhibiting agent on the oxidant layer according to a pattern, to partially inhibit the formation of the oxidant layer; and forming a polymer layer by exposing the surface to a monomer vapour at a polymerisation temperature of 20-95 ° C. under atmospheric pressure.

### TECHNICAL FIELD

The present disclosure relates to a method for manufacturing a patterned a film comprising at least one polymer layer. The present disclosure also relates to a film comprising at least one polymer layer. The present disclosure further relates to a device comprising the film as well as to a system for manufacturing a patterned film comprising at least one polymer layer.

### BACKGROUND

Oxidation of azulene monomer undergoes polymerisation at 1- and 3-position to give 1,3-polyazulene. Polyazulene (PAz) is a conducting polymer with a high capacitance and redox behaviour. PAz films may be produced by electrochemical, chemical and photochemical polymerisation. Because of their electronic properties, conducting and redox behaviour as well as the fast charge-discharge nature, PAz films may be useful in applications related to the field of electronics, antistatic coatings, dye-sensitised or organic solar cells, electrochemical transducers, electrochromic devices, electroluminescent devices, organic light emitting diodes (OLED's), and supercapacitors. In order to be suitable for the above-mentioned applications, PAz films may need to be highly organised, homogenous, transparent and thin. Of the current methods, electrochemical polymerisation may produce non-uniform films and require a conducting electrode substrate, thus limiting its fabrication only to electrode materials whereas oxidative chemical synthesis may give the material in powder or granular forms. Further casting or processing may not be possible due to the insoluble nature of PAz.

On the other hand, also conducting poly-3,4-ethylenedioxythiophene (PEDOT) films and its copolymer films are known and used in different fields. These films can be manufactured in the same manner as PAz films.

Because the production of high-quality PAz and/or PEDOT films having the desired properties may be challenging with the current production methods, new approaches may be needed. It would also be ideal to be able to produce patterned films that could be used either as such or as basis for further products.

### SUMMARY

The present description relates to a method for manufacturing a patterned film on a substrate, the method comprising
forming an oxidant layer on a substrate by applying a solution comprising an oxidant on the surface of the substrate by coating;
drying the oxidant layer;
applying an inhibiting agent on the oxidant layer according to a pattern, to partially inhibit the formation the oxidant layer; and
forming a polymer layer by exposing the surface to a monomer vapour at a polymerisation temperature of 20-95° C. under atmospheric pressure.

The present description also relates to a device comprising a film obtainable by a method as described herein.

The present description further relates to a system for manufacturing a patterned film on a surface of a substrate, the system comprising
an oxidant unit configured to apply a solution comprising an oxidant on the surface by coating, for forming an oxidant layer on the surface;
means for drying the oxidant layer;
means for applying an inhibiting agent on the oxidant layer according to a pattern; and
a chamber configured to expose the surface to a monomer vapour at a polymerisation temperature of 20-95° C. under atmospheric pressure for forming a polymer layer.

### BRIEF DESCRIPTION OF THE DRAWINGS

The accompanying drawings, which are included to provide a further understanding of the embodiments and constitute a part of this specification, illustrate various embodiments.

FIGS. 1A-IC schematically illustrate a film formed on a substrate, according to an embodiment of the present method, and various steps of the method.

FIG. 2 illustrates a vapour phase polymerisation cell for carrying out the vapour phase polymerisation, according to an embodiment.

FIG. 3 illustrates a set up for a continuous VPP process for substrates according to an embodiment.

FIG. 4 visualises some rubber stamp generated patterns.

FIG. 5 visualises a printed pattern according to an embodiment.

FIG. 6 visualises a printed pattern according to another embodiment.

FIG. 7 shows an AFM image from the edge of the printed region as well as a height profile at a given location from the image.

### DETAILED DESCRIPTION

The present description relates to a method for manufacturing a patterned film on a substrate, the method comprising
forming an oxidant layer on a substrate by applying a solution comprising an oxidant on the surface of the substrate by coating;
drying the oxidant layer;
applying an inhibiting agent on the oxidant layer according to a pattern, to partially inhibit formation of the oxidant layer; and
forming a polymer layer by exposing the surface to a monomer vapour at a polymerisation temperature of 20-95° C. under atmospheric pressure.

The present method uses the vapour deposition polymerisation method described in WO 2020/221958 and WO 2019/211510, the contents of which are herein incorporated by reference. In particular, their experimental sections are incorporated by reference as illustrating the formation of oxidant layer and the polymerisation, in so far as they are not described in this description.

In the present method, firstly an oxidant layer is formed on a surface of a substrate by coating. Thereafter, the oxidant layer is either dried or allowed to dry. If it is dried, this is carried out as explained below, drying being preferred. After the oxidant layer is dry, i.e. the solvent used has evaporated, an inhibiting agent is applied on the oxidant layer. The inhibiting agent is applied according to a pattern to partially inhibit the formation of the oxidant layer. The inhibiting agent is applied to those parts of the oxidant layer where it is not desired to form a polymer layer in the subsequent step. The functioning of the de-oxidating agent is explained in more detail below. After this selective inhibiting, a polymer layer is formed by vapour phase polymerisation, as is described in WO 2022/221958.

The steps of the method are thus performed in the order described above. The method may also comprise further steps, as will be apparent from this description.

In the context of this specification, unless otherwise specified, the term “polymerisation temperature” may refer to the temperature of the monomer vapour(s) during the polymerisation vapour phase polymerisation. Polymerisation temperature may also refer to the temperature of a reaction chamber or cell, inside of which the polymerisation is carried out. Further, the term “surface” denotes the surface of the substrate or the surface obtained in a preceding step, which is further treated. Also, the term “deposition surface” may be used, interchangeably with the term “surface”. In the context of this specification, the term “surface” may thus refer to a surface of the substrate as such or to a surface covered with an oxidant layer. The “surface” may further refer to a surface covered with a polymer layer, which lies on top of the oxidant layer. It may further refer to a surface covered with sequential layers of the oxidant and/or polymer layers, wherein the first layer on the surface of the substrate is the oxidant layer followed by the polymer layer, and so on. The “surface” may thus change during the (deposition) process when chemicals are applied onto the surface.

The term “film” should be understood in this specification, unless otherwise stated, as referring to a structure having its lateral dimensions substantially larger than its thickness. In that sense, a film may be considered as being a “thin” structure. The expression that the film is “situated on” the surface of the substrate should be understood in this specification, unless otherwise stated, as meaning that the film is formed to lie on or upon the substrate.

By the term “temperature of the surface” it is meant in practice the temperature of the substrate. Preferably, the temperature of the substrate and thus of the surface is controlled separately, using for example temperature sensors and heating/cooling arrangements. The term “polymerisation temperature” means the temperature of the monomer vapour.

By the terms “inhibit the action of the oxidant” and “inhibit the formation of the oxidant layer” it is typically meant that the inhibiting agent in question prevents the action of the oxidant. Alternatively, it may have a significant effect on the oxidant, so as to if a layer of oxidant is formed, it is not formed to a sufficient degree for a polymer layer to form on those parts where the inhibiting agent has been applied.

The quality of the film obtained depends significantly on the method of manufacturing, and is influenced, i.a., by the thickness of the different layers and their uniformity. With the present method, it has been observed that good quality films can be obtained, such as films with good sheet resistance and surface roughness, as well as the homogeneity of the film. These are believed to be due to the selected coating methods as well as to the difference in temperature between the substrate surface and the monomer vapour. Indeed, the temperature difference between the substrate (the surface of the substrate) and cell/chamber (monomer vapour temperature) controls the rate of condensation of monomers to the substrate surface and the gradient of monomer vapour near the surface. The substrate temperature and monomer deposition/condensation rate influence the properties of films.

According to an embodiment, the polymer layer consists of a polymer or copolymer of azulene and/or 3,4-ethylenedioxythiophene. Indeed, according to an embodiment, the monomer vapour comprises azulene, 3,4-ethylenedioxythiophene, and combinations thereof. The polymer may thus be a homo- or a copolymer, as desired.

According to another embodiment, the monomer vapour comprises, in addition to azulene and/or 3,4-ethylenedioxythiophene, a further monomer selected from a group consisting of pyrrole, aniline, thiophene, and phenylene.

In one embodiment, in vapour phase polymerisation, the surface is exposed to at least azulene monomer vapour and at least one further monomer vapour. In a further embodiment, in vapour phase polymerisation, the surface is exposed to at least 3,4-ethylenedioxythiophene monomer vapour and at least one further monomer vapour. In a still further embodiment, in vapour phase polymerisation, the surface is exposed to azulene and 3,4-ethylenedioxythiophene monomers vapour.

In another embodiment, in vapour phase polymerisation, the surface is exposed to at least azulene monomer vapour and/or 3,4-ethylenedioxythiophene (EDOT) and at least one further monomer vapour selected from a group consisting of pyrrole, aniline, thiophene, and phenylene. In a further embodiment, the at least one further monomer vapour is selected from pyrrole, aniline, thiophene, phenylene, furans, ethylene, tetrafluoroethylene, vinyl chloride, propylene, methyl methacrylate, methyl acrylate, vinyl acetate, ethylene vinyl acetate, styrene, 1,3-butadiene, isoprene(2-methyl-1,3-butadiene), chloroprene(2-chloro-1,3-butadiene), isobutylene(methylpropene), propylene, methylpentene, butane-1, isobutylene as well as any other linear olefins, cyclic olefins, vinyl ether, allyl ether, vinyl ester and allyl ester. Various mixtures of these monomers may also be used, resulting in copolymers. The resulting polymer may thus be for example polyethylene (PE), polypropylene (PP), polymethylpentene (PMP), polybutene-1 (PB-1); polyolefin elastomers (POE) such as polyisobutylene (PIB), ethylene propylene rubber (EPR), or ethylene propylene diene (M-class) rubber (EPDM rubber).

The inhibiting agent reduces and/or passivates the oxidant layer on those areas where it is applied thereon. This will prevent polymerisation of the monomer(s) on those areas. The inhibiting agent is thus used to form a negative of the film pattern that is aimed at.

According to an embodiment, the inhibiting agent is selected from a group consisting of reducing agents and complexing agents. The function of the inhibiting agent is to inhibit the action of the oxidant, so that once the monomer vapour is applied, no polymer is formed on those areas where the oxidant is inhibited. It is believed that with the present method, it is possible to make more precise patterns, i.e. smaller and more accurate patterns, than if the oxidant was applied according to a pattern. This is believed to be due for example to the nature of the oxidant solution, such as its flow properties. The present method further allows the formation of a uniform and even oxidant layer, which thus remains even and uniform in the non-de-inhibited areas, thus allowing the formation of films with high conductivity and good quality. It is also believed that some application methods lead to more accurate end results, as the properties of the final, patterned film depend on the quality of the oxidant layer, mainly its uniformity and evenness. Typically spin coating, spray coating, aerosol deposition, physical vapour deposition (PVD), chemical vapour deposition (CVD), atomic layer deposition (ALD), sol-gel deposition, electroplating, roll-to-roll deposition and dip coating will lead to more accurate oxidant layers than other methods of application of the oxidant solution. Indeed, when using these coating methods, it is possible to accurately control the amount of oxidant and thus the thickness of the layer. For example, in case of spin coating, this can be achieved by adjusting the spinning speed and the volume used, and in spray coating also the volume used. In dip coating, the control can be achieved by controlling the speed of dipping. Similar level of control is not achievable by soaking methods, such as immersion. Spin coating, spray coating and dip coating may be preferred.

As is discussed in more detail below, the oxidant may be selected from a group consisting of iron (II), iron (III), cerium (IV) and copper (II) salts. Thus, when the inhibiting agent is a reducing agent, it reduces the metal salt to a lower oxidation state, for example Fe (III) to Fe (II). This passivates the oxidant. When the inhibiting agent is a complexing agent (also called chelating agent), it complexes, i.e. sort of encapsulates, the oxidant (for example Fe (III)), which thereafter can no longer react with the monomer(s). The oxidant may be for example iron (III) p-toluenesulfonate, iron (III) trifluoromethanesulfonate, iron (III) chloride, p-toluenesulphonic acid, iodine, bromine, molybdophosphoric acid, ammonium persulfate, DL-tartaric acid, polyacrylic acid, copper chloride, copper bromide, ferric chloride, naphthalenesulfonic acid, camphorsulfonic acid, iron (III) toluene sulfonate, iron (III) perchlorate, Cu(ClO₄)₂·6H₂O, cerium (IV) ammonium nitrate, cerium (IV) sulfate and any mixtures thereof. The inhibiting agent is selected such that it has a sufficient potential to inhibit the action of the oxidant to a sufficient degree. This is particularly important in the case of reducing agents.

According to a preferred embodiment, the surface is not cleaned between the application of the inhibiting agent and the polymerisation by vapour deposition. It has indeed been observed that such a cleaning is not necessary, and good results are obtained even without cleaning.

According to an embodiment, the inhibiting agent is selected from a group consisting of ascorbic acid; oxalic acid; sodium thiosulfate trisodium citrate; hydrazine and its derivatives; citric acid; lithium aluminium hydride (LiAlH₄); sodium borohydride (NaBH₄); dithionate, thiosulfate, and iodide ions; formic acid; reducing sugars (galactose, glucose, glyceraldehyde, fructose, ribose, and xylose); ethylenediaminetetraacetic acid (EDTA); trans-1,2-diaminocyclohexanetetraacetic acid (CDTA); trimethylenediaminetetraacetic acid (TMDTA); N-(2-hydroxyethyl)ethylenediamine,N,N′,N′-triacetic acid (HEDTA), N,N′-bis(2-hydroxybenzyl)ethylenediamine-N,N′-diacetic acid (HBED); Catechol; 3,5-disulfocatechol (TIRON); salicylate; glycine. Of these, citric acid; oxalic acid; citrates; ethylenediaminetetraacetic acid (EDTA); trans-1,2-diaminocyclohexanetetraacetic acid (CDTA); trimethylenediaminetetraacetic acid (TMDTA); N-(2-hydroxyethyl)ethylenediamine,N,N′,N′-triacetic acid (HEDTA), N,N′-bis(2-hydroxybenzyl)ethylenediamine-N,N′-diacetic acid (HBED); Catechol; 3,5-disulfocatechol (TIRON; salicylate; and glycine are mainly complexing agents (which however have some capability to reduce, in particular Fe(III)), while the others are reducing agents.

According to another embodiment, the inhibiting agent is applied by printing or stamping. Printing can be carried out for example with an ink jet printer, which typically has a nozzle size in the micrometre scale. Other possible printing techniques are micro contact printing and gravure printing. The stamping can be carried out by rubber stamping. Some further possibilities are tape-casting, press printing, screen printing, offset printing, and flexographic printing or 3D printing (which 3D printing could also be used for the manufacturing of the substrate). The patterned film can be applied as one layer or it may be applied as several consecutive layers, depending on the monomer(s) used as well as the desired film thickness.

Further, the present method may also comprise repeating the steps of forming an oxidant layer, drying the oxidant layer, applying an inhibiting agent, and forming a polymer layer by vapour phase polymerisation. Such steps can be repeated several times if so wished. The monomers used may also be different in the different layers. The oxidant layer may thus be re-applied on the patterned film, and another pattern created on the new oxidant layer with the inhibiting agent. This process allows the formation of different areas in the final film, with different thicknesses. As the polymer layer is electrically conductive, such structure can have areas of different conductivity.

In one embodiment, the total thickness of the film is 20 nm-50 μm, or 50 nm-10 μm, or 100 nm-1 μm, or 200 nm-500 nm.

In one embodiment, the method is carried out as a batch process. I.e. one film can be prepared at one go, e.g. in a reaction chamber or a cell, wherein the different method steps can be carried out. In one embodiment, the method is carried out as a continuous process, for example as a roll-to-roll process or a dipping process. I.e. the substrate can be moved from one method step into the others without interruptions. E.g. being first coated with the oxidant, then dried, followed by application of the inhibiting agent, and then exposed to monomer vapour(s). In a continuous process, several films may be prepared simultaneously in parallel.

In one embodiment, the film has a rigid structure. In another embodiment, the film is flexible. In a further embodiment, the film may be rolled up.

In one embodiment, at least one catalyst and/or at least one catalyst additive are/is used in vapour phase polymerisation. In one embodiment, the at least one catalyst and/or catalyst additive is selected from the following: Ziegler-Natta catalysts, AlCl₃, TiCl₃, cerium(IV) ammonium nitrate, cerium(IV) tosylate, Fe(III)tosylate, pyridine, p-toluenesulphonicacid (p-TSA), diethyleneglycol (DEG), molybdophosphoric acid, molybdo-2-vanadophosphoricacid, poly(styrenesulfonate) (PSS), Fe(III)alkylbenzenesulfonates, iodine, bromine, pyrocatechovoilet, benzenesulfonicacid (BSA), p-toluenesulfonicacid (TSA), dodecylbenzenesulfonicacid (DBSA), butylbenzenesulfonicacid (BBSA), glycerol, trialkylaluminum-free modified methylaluminoxane, TEMPO ((2,2,6,6-Tetramethylpiperidin-1-yl)oxyl or (2,2,6,6-tetramethylpiperidin-1-yl)oxidanyl), peroxides, chloride or iodide of Ti, V, Zr, Cr, W, Co and aluminium (Mg or Li) alkyl TiCl₄ with alkyl aluminium compounds in hydrocarbon solvent, titanium supported on magnesium salts, VOCl₃, VCl₄, or VO(OR)₃, with aluminium alkyls RAlCl₂, a transition metal (Zr, Ti or Hf) sandwiched between cyclopentadienyl rings, Cr, Mo, Co or Ni supported on alumina, silica, zirconia or activated carbon, Cr/SiO₂, Zr/Al₂O₃ and Ti/MgO, supported chromium oxide, bis(arene)chromium chromium oxides supported on silica, alumina or titania.

In one embodiment, vapour phase polymerisation is continued until the thickness of the polymer layer is at least 10-100 nm, or 20-90 nm, or 30-80 nm, or 40-60 nm. For certain applications it may be useful to have a thicker film i.e. several layers of polymer, whereas for other applications a thinner film with less layers may be useful. The number of layers i.e. the thickness of the film may affect the active material content and configuration at micro or nano level, which may affect the film properties such as conductivity, capacitance, sheet resistance, band gap, active surface area, and transparency.

The substrate may serve as a carrier or support structure for the film. The substrate can be changed and the material of the substrate can vary according to the application to which the film is to be used. In one embodiment, the substrate is rigid. In one embodiment, the substrate is flexible, bendable, and/or can be rolled up.

In one embodiment, the polymer layer is a 1,3-polyazulene layer. In another embodiment, the film comprises at least one 1,3-polyazulene layer. In a further embodiment, the film consists of at least one polymer layer formed of PAz, or of a copolymer, wherein one of the monomers is azulene, or of any combination thereof. In a still further embodiment, the film is a PEDOT film, or a copolymer with 3,4-ethylenedioxythiophene with another monomer. In an embodiment, the film is a copolymer of 3,4-ethylenedioxythiophene and azulene. In one embodiment, the film consists of one or more polymer layers formed of any of the polymers and copolymers listed above.

In one embodiment, the polymer layer is formed at least on one side of the substrate. In another embodiment, the polymer layer is formed on a top and a bottom side of the substrate.

In one embodiment, vapour phase polymerisation is continued for 1-20 minutes, or 2-16 minutes, or 4-8 minutes. The polymerisation time may affect the thickness of the polymer layer. If the polymerisation is continued for a longer time, the polymer layer may be thicker. It may also be possible that after a certain time period the layer will no longer get thicker although the polymerisation is continued. This may be due to the fact that once the surface covered with an oxidant layer is completely occupied by polymer, the monomer is unable to reach the oxidant even if polymerisation is continued for a longer time. It may only deposit monomer as such, but it will not be polymerised. Further, the deposited non-polymerised monomer may be washed or rinsed away during the washing of the film leaving only polymerised film behind. Such washing may be carried out by any suitable liquid, such as acetonitrile.

The polymer layer is formed on the surface by atmospheric pressure vapour phase polymerisation (VPP). VPP is a polymerisation technique where only the monomer is converted into vapour phase. The VPP carried out in atmospheric pressure has the added utility of being easy to control. It may not need pressure control or sophisticated device or vacuum oven. The method may be used also for production of large area films.

In one embodiment, the VPP is carried out in a reaction chamber or cell. In another embodiment, the temperature of the reaction chamber or cell is controlled. In one embodiment, the temperature of the reaction chamber or cell is controlled with thermostat baths.

In one embodiment, during vapour phase polymerisation, the temperature of the surface is 21-75° C., or 25-75° C., or 30-60° C., or 35-65° C., 40-50° C., or 45-55° C.

In one embodiment, during vapour phase polymerisation, the polymerisation temperature (i.e. the temperature of the reaction chamber) is 20-90° C., or 35-85° C., or 40-80° C., or 45-75° C., or 50-70° C., or 55-65° C. The use of a low polymerisation temperature has the added utility of saving costs as less electricity is used. It may also be suitable for temperature sensitive substrates, such as biomolecule treated substrates or plastic and other delicate substrates.

In one embodiment, during vapour phase polymerisation, the temperature of the surface differs from the polymerisation temperature, i.e. there is a temperature difference that is larger than 0° C. The temperature difference can be for example >0-30° C., or 1-25° C., or 5-20° C., or 10-15° C. In one embodiment, during vapour phase polymerisation, the temperature of the surface is >0-30° C., or 1-25° C., or 5-20° C., or 10-15° C. lower than the polymerisation temperature, or >0-20° C., or 1-15° C., or 5-10° C. higher than the polymerisation temperature. In one embodiment, during vapour phase polymerisation, the temperature of the surface is >0-30° C., or 1-30° C., or 1-25° C., or 2-25° C., or 3-25° C., or 4-20° C., or 5-20° C., or 10-15° C. lower than the polymerisation temperature, or >0-20° C., or 1-15° C., or 2-15° C., or 3-15° C., or 4-10° C., or 5-10° C. higher than the polymerisation temperature. The vapour phase polymerisation can be carried out in a cell or a reaction chamber, but it may also be carried out without such device. It is however preferred to use a cell or reaction chamber for easier temperature control and formation of monomer vapour. The reaction chamber may also be a large space, for manufacturing large series of products, for example.

Typically, the temperature of the surface is lower than the temperature of the monomer, i.e. the polymerisation temperature. In practice, it has been observed that a temperature difference of about 1° C. is already sufficient to have a positive effect on the condensation rate of the monomer on the surface. The temperature difference has been observed to have a positive effect on the properties of the obtained film. For example, it may have an effect on one or more of the conductivity of the film, type of defects on the film, transparency of the film, surface roughness of the film, heat resistance of the film and transmittance of the film.

The temperature of the surface may affect the sheet resistance of the film. It may increase or decrease the sheet resistance. Further, it may affect the stability of the film configuration and in some cases avoid fracture due to stress during washing. Decrease in sheet resistance after temperature treatment may mean either that a doping level of the conductor or semiconductor is decreasing or that polymer chain structures are reorganizing or breaking. In one embodiment, the temperature of the surface is at least, or above, 0° C. In another embodiment, the temperature of the surface is at least, or above, room temperature.

In one embodiment the polymerisation temperature (i.e. the temperature of the reaction chamber) is 20-95° C. and the temperature of the surface is 25-75° C.; the polymerisation temperature is 25-74° C. and the temperature of the surface is 26-75° C.; the polymerisation temperature is 25-90° C. and the temperature of the surface is 25-75° C.; or the polymerisation temperature is 35-85° C. and the temperature of the surface is 30-70° C.; or the polymerisation temperature is 40-80° C. and the temperature of the surface is 35-65° C.; or the polymerisation temperature is 45-75° C. and temperature of the surface is 40-50° C.; or the polymerisation temperature is 50-60° C. and temperature of the surface is 45-55° C.

In one embodiment, the cell or the reaction chamber contains a saturated amount of monomer vapour(s). The amount may depend on the size of the cell or the chamber.

In one embodiment, the oxidant is selected from a group consisting of iron (II), iron (III), cerium (IV) and copper (II) salts. In an embodiment, the oxidant is selected from a group consisting of iron (III)-p-toluene sulfonate (FETOS), FeCl₃, CuCl₂, CuBr₂, and iron (III) trifluoromethanesulfonate (Fe(OTf)₃). The oxidising strength of the oxidants may vary. The film structure and polymer configuration may change depending on which oxidant is used. The above listed oxidants are believed to be able to allow formation of films of high quality.

In one embodiment, the concentration of the solution comprising the oxidant is 60-500 mM, or 70-480 mM, or 120-320 mM, or 180-240 mM. The solvent in the solution comprising the oxidant may be selected from a group consisting of organic solvents such as n-butanol, methyl alcohol, 2-butyl alcohol, n-propyl alcohol, iso-propanol, ethyl cellosolve, ethyl alcohol, ethyl acetate, acetonitrile and methyl ethyl ketone and mixtures thereof. The purpose of the oxidant is to deprotonate the monomer and initiate the polymerisation. In one embodiment, the solution consists of a solvent and an oxidant. In one embodiment, the oxidant layer is dried before polymerisation. By drying the oxidant layer before polymerisation, one is able to remove traces of solvents before proceeding into the polymerisation step. In one embodiment, the polymerisation reaction is a gas-solid reaction at their interface.

The oxidant solution may also comprise a base inhibitor. Base inhibitors decrease the activity of the oxidant and lower the rate of polymerisation. This may alter the conductivity of the final polymer. The base inhibitor may be selected from the group consisting of amine-based compounds and nitrogen atom-containing saturated or unsaturated heterocyclic compounds such as a pyridine-based, imidazole-based, or pyrrole-based compounds, water vapor, glycerol, and glycol derivatives, and mixtures thereof.

In one embodiment, the solution comprising the oxidant is spin coated on the surface. In one embodiment, the solution comprising the oxidant is spin coated on the surface at 1000-2800 rpm for 20-90 s. In one embodiment, the solution comprising the oxidant is spin coated on the surface at 1200-2600 rpm, or 1400-2400 rpm or 1600-2200 rpm, or 1800-2000 rpm for 30-80 s, or 40-70 s, or 50-60 s. In one embodiment, the oxidant coated surface is dried before vapour phase polymerisation. In one embodiment, the oxidant coated surface is dried on a hot plate at a temperature of 70-110° C. for 10-150 s, e.g. at 90° C. for 90 s.

The different oxidants may behave differently at different temperatures, and one oxidant may also behave differently at different temperatures. It may thus be necessary to carry out a few simple tests to find out the optimal conditions.

In one embodiment, the method comprises the step of cleaning the surface before formation of oxidant layer. In one embodiment, the substrate may be cleaned by ultra-sonication with a solvent. In one embodiment, the solvent for the ultra-sonication may be selected from the group consisting of organic solvents. In an embodiment, the solvent for the ultra-sonication is selected from a group consisting of acetone, ethanol, water and mixtures thereof.

In one embodiment, the cleaned surface may be dipped into a hot solution. In one embodiment, the cleaned surface may be dipped in hot solution of H₂O:NH₄OH (25%):H2O2 (30%) as 5:1:1 volume ratio at a temperature of 50-100° C., e.g. 85° C. The cleaning has the added utility of removing any organic impurities left behind on the surface. In one embodiment, an oxygen plasma treatment may follow. Oxygen plasma treatment refers to a plasma treatment where oxygen is introduced to a plasma chamber. The oxygen plasma treatment has the added utility to further clean the substrate. Oxygen is the most common gas used in plasma cleaning technology due to its low cost and wide availability.

In one embodiment, the method comprises, after vapour phase polymerisation, the step of annealing the film at a temperature of 60-100° C. In one embodiment, the temperature of the annealing step is 70-90° C. or about 80° C. In one embodiment, annealing of the film is continued for 140-40 s, or 50-120 s, or 60-90 s, e.g. for 120 s. Annealing may be done on a hot plate or in an oven. In an embodiment, the system thus comprises a heating unit configured to anneal the film at a temperature of 60-100° C.

In one embodiment, after annealing, the film is cooled to room temperature. The film can be annealed to avoid stress fracture of the film during the washing step. In one embodiment, the annealed and cooled film is washed. In one embodiment, the washing comprises dip washing the film with MeCN and/or with ethanol. The washing has the added utility of removing unreacted oxidant, monomer and any other impurities that may decrease the conductance. The solvent used may affect the sheet resistance of the film. The sheet resistance may be reduced e.g. due to water traces present in the solvent. In one embodiment, after washing, the film is dried under dry nitrogen gas stream.

In one embodiment, the substrate is non-conductive. In one embodiment, the substrate comprises or consists of glass, paper, cellulose, textile, fabric, wood, leather, cotton, ceramic, quartz, rubber, polymer, or any combination of these. In one embodiment, the glass may be a microscope glass slide or fluorine-doped tin oxide (FTO) glass or indium tin oxide (ITO) coated glass. A polymer film manufactured according to the present method may also be used as a substrate for manufacturing of further products. In one embodiment, the non-conductive substrate comprises or consists of a polymer. The polymer may be polyethylene terephthalate (PET), poly-3,4-ethylenedioxythiophene-polystyrene sulfonate (PEDOT:PSS), polycarbonate (for example as sold under the tradename of Makrofol™ such as Makrofol PC or Makrofol DE 1-1), polyethylene naphthalate (PEN), polyester, polyamide (PI), polyester sulfone (PES), polystyrene (PS), and amorphous polyester (A-PET or PET-G), and mixtures thereof. In another embodiment, the rubber is selected from a group consisting of ethylene propylene rubber (EPR) and ethylene propylene diene monomer (M-class) rubber (EPDM rubber). Still further, the substrate may be a semiconductor material, such as based on Si, Ge, or elements from the group III-V (such as In, As, Ga, etc.), or cellulose nanotubes (CNT), silver nanowire materials, graphene or other similar combination materials and substrates.

In one embodiment, thickness of the substrate is 5 μm-2 cm. The thickness of the substrate may vary depending on the purpose of the use of the film or the material of the substrate.

The expression that the substrate is “non-conductive” should be understood in this specification, unless otherwise stated, as meaning that the substrate has a sheet resistance of 10 Mohms/square (M/□) or higher.

In one embodiment, the substrate is conductive e.g. fluorine-doped tin oxide (FTO) glass or indium tin oxide (ITO) coated glass or gold (Au) coated substrate or silver (Ag) coated substrate or silicon. Depending on the application, a conductive or non-conductive substrate may be useful.

The roughness of the film, sometimes also referred to as surface roughness, is a measure of the deviations in the direction of the normal vector of a real surface from its ideal form. If the deviations are large, the surface is rough; if the deviations are small, the surface is smooth.

In one embodiment, the average roughness (Ra) of the film is below 200 nm, or below 150 nm, or below 100 nm, or below 80 nm, or below 50 nm, or below 25 nm, or below 15 nm, or below 10 nm.

Roughness average values of the PAz films are obtained from the atomic force microscope (AFM) images by using WSXM 5 software. The roughness average is the mean of the difference, in absolute value, between the average height and the height of each single point of the sample. This number varies with the interval range. It shows how uniform or rough the PAz film is. It may be calculated with the following equation (1).

$$r . a = \frac{{\sum }_{i , j} \vert {a}_{i , j} - < a > \vert}{N} \qquad ( 1 )$$

wherein
r.a stands for roughness average,
<a> is the average height,
aij is the height at each single point of the sample,
i and j denote the position of single points (entries) on two dimensional surface, and
N is the number of “aij” points considered on the surface.

Root mean square (rms) of the roughness of the films is obtained from the AFM images by using WSXM 5 software. It may be calculated with the following equation (2).

$$rms = \sqrt{\frac{{\sum }_{i , j} {( {a}_{i , j} - < a > )}^{2}}{N}} \qquad ( 2 )$$

This number varies with the interval range. Minimum value: minimum value of the height of the interval of interest. Maximum value: maximum value of the height of the interval of interest.

In one embodiment, the roughness of the film is measured before the optional annealing and washing steps. This may be useful to check how these steps affect the roughness of the film since it is an important property of the film.

A smooth film has the added utility that the conductivity and transmittance thereof may remain even over the whole surface of the film.

In one embodiment, the transmittance of the film is 10-95%, or 20-85%, or 30-75%. In one embodiment, the transmittance of the film is measured at 300-1100 nm, or at 550-1100 nm, or at 550 nm.

Agilent 8453 spectrometer can be used to record the UV-Vis spectra. The % Transmittance (% T) is calculated from the absorbance (Abs) data by using following equation (3).

$$( \% T ) = ( 10 \hat{} ( - Abs ) ) * 100 \qquad ( 3 )$$

In one embodiment, the areal capacitance of the film is 0-10 mF/cm², or 0.01-9 mF/cm², or 0.05-8 mF/cm², or 0.2-7 mF/cm², or 1-5 mF/cm², or 2-4 mF/cm². In one embodiment, the areal capacitance of the film is 0-25 mF/cm², or 0.01-15 mF/cm² or 0.05-10 mF/cm², or 0.2-7 mF/cm², or 1-5 mF/cm², or 2-4 mF/cm².

In one embodiment, the volumetric capacitance of the film is 200-2000 F/cm³, or 250-1500 F/cm³, or 300-1200 F/cm³, or 500-1000 F/cm³, or 600-800 F/cm³. In one embodiment, the volumetric capacitance of the film is 5000-18000 F/cm³, or 6000-17500 F/cm³, or 7000-17000 F/cm³.

In one embodiment, the areal capacitance (CA) and volumetric capacitance (CV) values are determined by electrochemical characterisation with cyclic voltammetry. The charge (Q) is calculated by integration of the cyclic voltammogram in the potential range −0.25 V to 0.9 V in the Origin software which is further processed by using equations (4) and (5) to obtain capacitance values.

$$\begin{matrix}Areal capacitance & CA = Q / ( Δ V * A )\end{matrix} \qquad ( 4 )$$

$$\begin{matrix}Volumetric capacitance & CV = Q / ( Δ V * V )\end{matrix} \qquad ( 5 )$$

wherein ‘ΔV’ is the potential window, ‘A’ is the area and ‘V’ is the volume of working electrode.

In one embodiment, the conductivity of the film is 0-3 S·cm, or 0.01-2 S·cm, or 0.05-1.5 S·cm, or 0.1-1.0 S·cm, or 0.3-0.8 S·cm, or 0.4-0.6 S·cm. The conductivity may be measured before or after the optional washing of the film. After the washing the conductivity value may be higher or lower than before the washing step. At low polymerisation temperatures, the conductivities are lower before the washing step. At high polymerisation temperatures, the conductivities are lower after the washing step.

In one embodiment, the sheet resistance of the film is 1-80 MΩ/□, or 2-70 MΩ/□, or 5-50 MΩ/□, or 10-40 MΩ/□, or 15-30 MΩ/□. In one embodiment, the sheet resistance of the film is 0.01-2 MΩ/□, or 0.05-1.5 MΩ/□, or 0.08-1.1 MΩ/□, or 0.2-1.1 MΩ/□, or 0.6-1 MΩ/□. The sheet resistance may be measured before or after the optional washing of the film. After the washing the sheet resistance value may be higher or lower than before the washing step. At low polymerisation temperatures, the sheet resistance values are lower after the washing step. At high polymerisation temperatures, the sheet resistance values are higher after the washing step.

In one embodiment, the sheet resistance is measured before the optional annealing and washing steps. This may be useful to check how these steps affect the resistance of the film.

Jandel model RM3000+ with cylindrical four point probe head can be used to obtain sheet resistance (rsheet) values for the polymer films. The specific resistance (r) of the film is obtained by multiplying sheet resistance with film thickness (d), equation (6).

$$r = rsheet d \qquad ( 6 )$$

The conductivity (s) of the film is obtained according to equation (7).

$$s = 1 / r \qquad ( 7 )$$

The method described in the current application has the added utility of producing highly organised, transparent, homogenous, multilayer thin films. Further, the method described in the current application has the added utility of being low cost, simple and fast due to atmospheric pressure controlled polymerisation, short reaction time, low temperature and low monomer loading.

The method described in the current application further has the added utility of allowing layer by layer preparation of the film which may be useful in different applications. The method described in the current application has also the added utility of allowing preparation of flexible thin films on plastic materials which may be used in bendable electronics. Further, the method allows the preparation of thin films of nanometre to micrometre scale.

The method described in the current application has the added utility of being suitable for the preparation of films with different properties, e.g. conductivities and roughness values, being thus useful for a variety of applications.

The present application further relates to a film obtainable by the present method, i.e. comprising at least one partial, patterned polymer layer formed by vapour phase polymerisation, wherein the film is situated on at least one surface of a substrate. According to an embodiment, the total thickness of the film is 10 nm-100 μm. All the variants and embodiments described above in connection with the method apply mutatis mutandis to the film.

The present description also relates to device comprising a film obtainable by a method as described above. All the variants and embodiments described above in connection with the method apply mutatis mutandis to the device.

The device may be for example an organic electrochemical transistor, an electrochemical transducer, an electrochromic device, an electroluminescent device, an electroluminescent display, an organic capacitor, a supercapacitor, a sensor, a biosensor, an energy harvesting device, an antistatic material, a photovoltaic device, a storage device, an electrode, a touch screen, a circuit board, an antenna, a field effect transistor, a photodetector, or a thermoelectric device. Some particularly interesting devices are electrodes and antennas, as the present method allows manufacturing conductive patterns directly on the surface of the substrate. In fact, the present method allows manufacturing various printed electronics, such as electronics to be used in clothing.

The present description further relates to a use of the film as defined above, as an antistatic coating or an electrode in/of an electronic device.

The present description still further relates to a system for manufacturing a patterned film on a surface of a substrate, the system comprising
an oxidant unit configured to apply a solution comprising an oxidant on the surface by coating, for forming an oxidant layer on the surface;
means for drying the oxidant layer;
means for applying an inhibiting agent on the oxidant layer according to a pattern; and
a chamber configured to expose the surface to a monomer vapour at a polymerisation temperature of 20-95° C. under atmospheric pressure for forming a polymer layer.

The parts of the system are in the consecutive order as described above. Optionally, the chamber is configured such that its temperature is different from the temperature of the surface, the difference being typically 0-30° C. Again, all the variants and embodiments described above in connection with the method apply mutatis mutandis to the system. When the surface is kept at another temperature than the polymerisation temperature, the system comprises means for keeping the surface at the desired temperature.

As mentioned above, the system preferably comprises at least one temperature control system for the substrate and the chamber, and optionally also temperature sensors in the chamber and on the heating block for the substrate to have an accurate and precise temperature control of both the chamber, i.e. the monomer vapour, and the surface of the substrate. The system preferably also has means for maintaining the desired temperatures, such as heating and/or cooling devices.

### DETAILED DESCRIPTION OF THE DRAWINGS

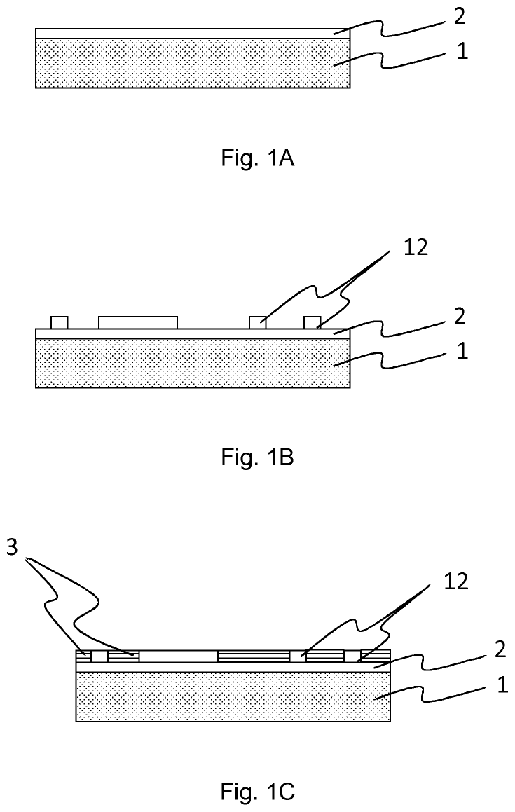

FIGS. 1A-1C schematically illustrate a film formed on a substrate, according to an embodiment of the present method, and various steps of the method. In FIG. 1A, an oxidant layer 2 has been formed on a surface of a substrate 4. In FIG. 1B, a pattern of inhibiting agent 12 has been applied on the oxidant layer. FIG. 1C illustrates the situation after the polymerisation, where a polymer film 3 has been formed on the surface of the oxidant layer 2 on those areas where its activity has not been inhibited.

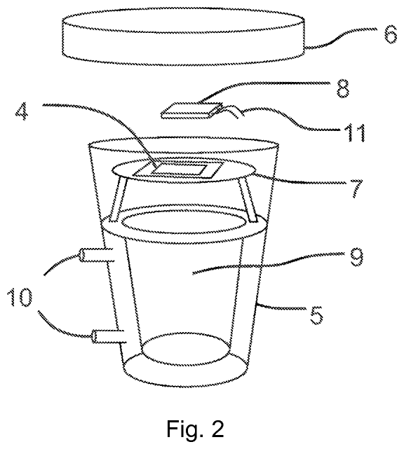

FIG. 2 illustrates a vapour phase polymerisation (VPP) cell for carrying out the vapour phase polymerisation, according to an embodiment. The polymerisation or reaction chamber 5 comprises a stand 7 for the substrate 4 and for the metal block 8. Thermostatic baths 10 are attached to the polymerisation chamber 5 to keep the temperature of the monomer vapour(s) 9 at the polymerisation temperature. The thermostatic bath 11 is attached to the metal block 8 to keep the temperature of the substrate 4 and thus the temperature of the surface at the controlled predetermined temperature. The polymerisation chamber 5 comprises a lid 6 which is used to close the polymerisation chamber 5.

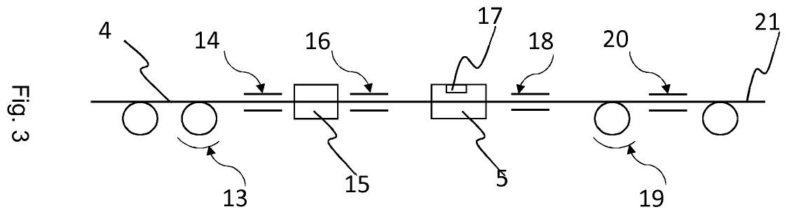

FIG. 3 illustrates a set up for a continuous VPP process for substrates according to an embodiment. A solution comprising the oxidant 13 is deposited on the substrate 4 by roll-to-roll technique, followed by drying 14 of the oxidant in an oven or with a heater. Thereafter, an inhibiting agent is applied by a printer 15, and the substrate is subjected to preheating 16, which can again be carried out in an oven or with a heater. In the next step, the substrate 4 is exposed to monomer vapour(s) in a polymerisation chamber 5. The speed of the rollers determines the time the substrate spends inside the chamber. Temperature of the substrate or the deposition surface is controlled with a heater and/or a temperature controller 17. Next, the film is annealed by heat with a heater 18, followed by washing with a washing liquid 19. Finally, the film is dried (with nitrogen gas) in a dryer 20 and a substrate covered with a patterned film 21 is obtained.

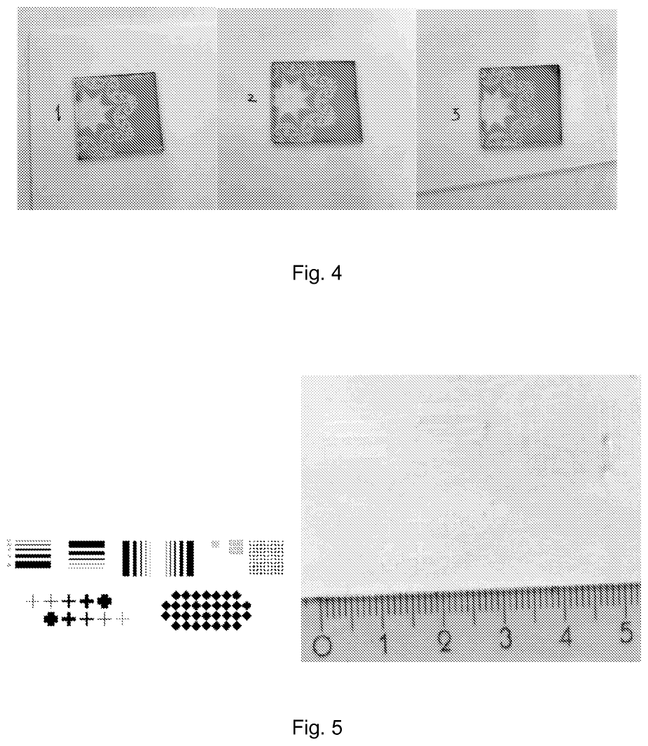

FIGS. 4 to 7 will be discussed in more detail in the Experimental part below.

### EXPERIMENTAL PART

Several different patterned films were prepared.

### Materials and Devices

The materials and devices used were as follows.
Acetone by VWR Chemicals
Ethanol by Altia Oy
Ammonium hydroxide by Sigma Aldrich,
Hydrogen peroxide by VWR Chemicals
n-butanol by Lab Scan
Pyridine by Lab Scan
Acetonitrile by Merck
3,4-ethylenedioxythiophene (EDOT) by TCI
Iron (III)-p-toluene sulphonate by Aldric, molar mass 677.52 g/mol
Sodium thiosulfate by Merck, molar mass 248.18 g/mol
Ascorbic acid by Merck, molar mass 176.13 g/mol
Oxalic acid by Merck, molar mass 126.07

The substrates were either glass or polyethylene terephthalate (PET). The glass was from Menzel-Glaser or RF France, cut into plates of 76 mm×26 mm. PET plates were from Goodfellow, ES30-FM-000225.

An ultrasonic cleaner by VWR, Ultrasonic Cleaner USC-THD as well as a conductivity measurement device Jandel, Model: RM3000+ with a measuring tip Jandel Se No: 376573, tip R 100 were used. An oxygen plasma cleaner by Harrick Plasma, Plasma Cleaner, PDC 002 was also used. The inkjet printer was by Dimatix.

### Cleaning of the Substrate

The substrates were cleaned before application of the oxidant. Cleaning of the glass plates was carried out by ultrasonication in acetone, water and ethanol, for 5 minutes in each liquid. Thereafter, a cleaning solution comprising 50 ml of water, 10 ml of ammonium hydroxide and 10 ml of hydrogen peroxide was prepared, heated to 80° C. and the plates were immersed therein for 5 minutes, in a vertical position. Thereafter, the substrates were rinsed with water, then with ethanol and allowed to dry for at least one hour. Immediately preceding the start of the experiment, the plates were cleaned by plasma with oxygen gas, for 5 minutes.

The PET plates were cleaned in a same manner by ultrasonication, followed by drying under ambient conditions and oxygen plasma cleaning for 5 minutes and immediately transported to a spin coater for oxidant coating.

### Oxidant Solution, its Preparation and Application

The oxidant was the same in all Examples, namely a solution comprising iron (III)-p-toluene sulphonate, n-butanol and pyridine. The oxidant solution was prepared by adding 0.160 mg of iron (III)-p-toluene sulphonate in an Eppendorf-tube and adding 850 μl of n-butanol. Thereafter, 11.3 μl of pyridine was pipetted to the tube and the solution was mixed. N-butanol was added until the total volume was 1 ml. In case any iron (III)-p-toluene sulphonate remained undissolved, ultrasonication was used to dissolve it.

After the oxygen plasma cleaning, the substrate was arranged on a rotating support and rotation was started. Thereafter, 60 μ/6.5 cm² (60 μl/square inch) of the oxidant solution prepared above was pipetted drop by drop during 20 seconds. After one minute of rotation, the substrate was transferred to a heated plate (90° C.) for 90 seconds.

### Preparation of the Inhibiting Solution and its Application

Various inhibiting agents were tested. Solid inhibiting agents were dissolved in a mixture of water (30 vol-%) and propylene glycol (70 vol-%) at a concentration of 0.01 M for those inhibiting agents that were printed. The inhibiting agents that were stamped were dissolved in water.

The inhibiting agent was applied either by rubber stamping or by inkjet printing. When a rubber stamp was used, it was wetted using a soft paper tissue wetted with the desired solution. Rubber stamps were used on the glass substrates and inkjet printing on the PET substrates. Rubber stamping was also tested on undried oxidant layer.

### Polymerisation

Polymerisation was also carried out in the same manner in all Examples. Namely, a VPP process was used, with EDOT as the sole monomer. Liquid EDOT was pipetted to the bottom of a heated VPP-chamber (75° C.), in an amount of 50 μl. Vaporisation was allowed to carry out for about 15 minutes. After application of the pattern with the inhibiting agent, the substrate was arranged in the chamber, the treated surface facing downwards. The substrate was kept in the chamber for 90 s, a hot copper plate (65° C.) was arranged on the substrate for 60 seconds, and the chamber was closed for another 90 s. The finished product was removed from the chamber and placed again on top of a heat plate (90° C.), the film facing upwards, for 90 s. In case of problems in the formation of the film, the process was repeated a few times. The cooled film and substrate were washed twice by acetonitrile and dried with nitrogen gas.

### Rubber Stamping

After preparation of the oxidant layer on a glass substrate, a rubber stamp was wetted with 0.01 M water solution of ascorbic acid (1), sodium thiosulfate (2) or oxalic acid (3) and stamp was pressed on fresh oxidant layer.

FIG. 4 shows the resulting images of PEDOT films on glass substrates after the VPP process (left-most ascorbic acid, middle sodium thiosulfate and right-most oxalic acid). A total depletion of PEDOT from stamp area was not possible. The resistance was much higher in the stamp area and extra washing steps had some influence to further improve depletion. Raman spectra and microscope images observe a response of PEDOT remnants also in the clear, stamp areas.

### Inkjet Printing

The printing was done using PET-substrates, and the inhibiting agent was printed after the oxidant layer had dried. Otherwise, the protocol was as described above.

In the printing process, a reducing agent was printed on the dried oxidant surface to produce patterns in which the polymerisation would not take place. For testing, two different solutions were made, 0.01 M trisodium citrate and 0.01 M thiosulfate, both in a mixture of 70% propylene glycol and 30% water. With these “inks”, a test pattern was first printed, shown on the left in FIG. 5, for establishing proper printing parameters for the best results. While the visual quality of the patterns produced were quite good (see the right part of FIG. 5), conductivity measurements made showed that the reducing of the oxidant was not complete and only a slight drop in conductivity was measured. In the Figure, the visibility of pattern is somewhat low because of high transparency of the VPP-film, due to its low thickness.

The result of the first attempt were thus only partly successful because the printed areas were also found to conduct electricity. However, the conductivity was lower. Total passivation of oxidant layer would need more optimisation of concentration of reducing agent and amount of liquid (drop size) in the printing process.

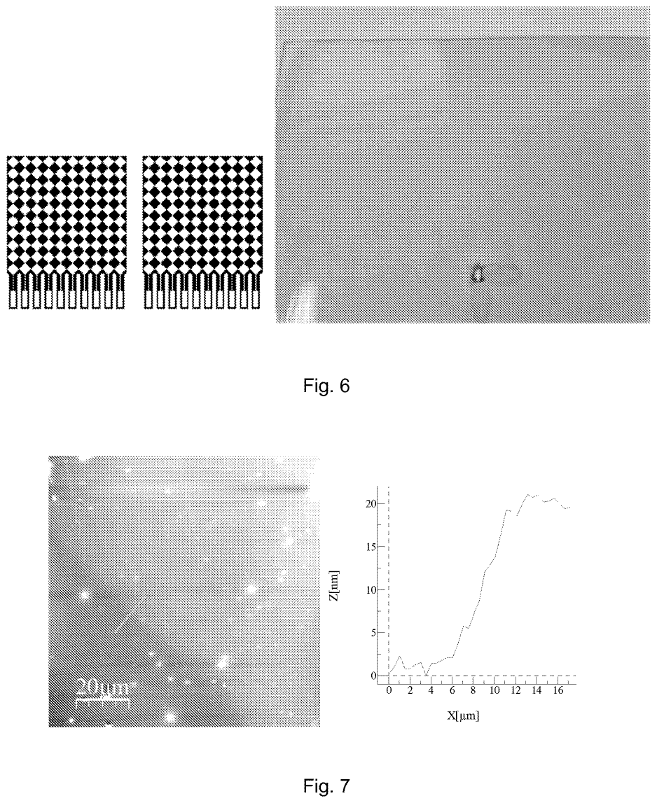

For second set of patterned films, a 0.01 M solution of ascorbic acid neutralized with NaOH to a pH of 5 was prepared again with the 70%/30% propylene glycol/water mixture. This time, a full array of electrodes was printed (left part of FIG. 6) and once again the visual quality of the printed pattern was great (right part of FIG. 6), but the conductivities were practically the same in the printed area as they were in the non-printed areas. The parameters had to be slightly changed from the initial tests as during the first print a raster print pattern was observed and using optical microscope an array of holes was seen on the surface instead of even coverage of the reducing agent. After parameter update, an even coverage was seen on the surface.

Atomic force microscope image from the edge of the printing pattern shows that the reducing agent induces ca. 20 nm decrease in the film thickness. FIG. 7 shows an AFM image from the edge of the printed region (left). Height profile was determined from the image (right). The line in the AFM image indicates the place where the profile was taken.

Also, in the second printing attempt, total passivation of the oxidant layer was not obtained. Electric conductivity was observed in the printed area. However, that would also be optimised with increasing the concentration and drop size of the printed reducing agent. The VPP-film was more than 20 nm thick (ca. 40 nm), thus the 20 nm thickness reduction does not wipe away the film completely. Also, the sheet resistance values tell that there is conducting layer on the printed areas. Sheet resistances were 290Ω/□ on the unprinted area and 320Ω/□ on the printed area.

### CONCLUSIONS

Even though the reducing of the oxidant was not complete, the small drop was the same across the whole pattern, meaning that continuous “hole” was created through the printed electrode patterns. From these results, it appears that even a more concentrated reduction solution would work, even as high as 0.236 M to match the concentration of FETOS in the oxidant solution.

1. A method for manufacturing a patterned film on a substrate, the method comprising:
forming an oxidant layer on a substrate by applying a solution comprising an oxidant on the surface of the substrate;
drying the oxidant layer;
applying an inhibiting agent on the oxidant layer according to a pattern, to at least partially inhibit polymerisation where the inhibiting agent is applied; and
forming a polymer layer on non-patterned areas the surface by vapour phase polymerisation, the vapour phase polymerisation comprising exposing the surface to a monomer vapour at a polymerisation temperature of 20-95° C. under atmospheric pressure.

2. The method according to claim 1, wherein the monomer vapour comprises azulene, 3,4-ethylenedioxythiophene, and combinations thereof.

3. The method according to claim 2, wherein the monomer vapour further comprises an additional monomer selected from a group consisting of pyrrole, aniline, thiophene, and phenylene.

4. The method according to claim 1, wherein the inhibiting agent is selected from a group consisting of reducing agents and complexing agents.

5. The method according to claim 4, wherein the inhibiting agent is selected from a group consisting of ascorbic acid; oxalic acid; sodium thiosulfate trisodium citrate; hydrazine and its derivatives; citric acid; lithium aluminium hydride (LiAlH₄); sodium borohydride (NaBH₄); dithionate, thiosulfate, and iodide ions; formic acid; reducing sugars; ethylenediaminetetraacetic acid; trans-1,2-diaminocyclohexanetetraacetic acid; trimethylenediaminetetraacetic acid; N-(2-hydroxyethyl)ethylenediamine,N,N′,N′-triacetic acid, N,N′-bis(2-hydroxybenzyl)ethylenediamine-N,N′-diacetic acid (HBED); Catechol; 3,5-disulfocatechol; salicylate; and glycine.

6. The method according to claim 1, wherein the inhibiting agent is applied by printing or stamping.

7. The method according to claim 1, wherein the vapour phase polymerisation is continued for 1-20 minutes.

8. The method according to claim 1, wherein the vapour phase polymerisation is continued until the thickness of the polymer layer is 10-100 nm.

9. The method according to claim 1, wherein during the vapour phase polymerisation the temperature of the surface is 25-75° C.

10. The method according to claim 1, wherein during the vapour phase polymerisation the polymerisation temperature is 25-90° C.

11. The method according to claim 1, wherein, during the vapour phase polymerisation, the temperature of the surface is 0-30° C. lower than the polymerisation temperature or 0-20° C. higher than the polymerisation temperature.

12. The method according to claim 1, wherein the oxidant is selected from a group consisting of iron (III)-p-toluene sulfonate, FeCl₃, CuCl₂, CuBr₂, and iron (III) trifluoromethanesulfonate.

13. The method according to claim 1, wherein the solution comprising the oxidant is spin coated on the surface.

14. The method according to claim 1, wherein a concentration of the solution comprising the oxidant is 60-500 mM.

15. The method according to claim 1, wherein the method comprises, after the vapour phase polymerisation, a step of annealing the film at a temperature of 60-100° C.

16. The method according to claim 1, further comprising repeating the steps of forming an oxidant layer, drying the oxidant layer, applying an inhibiting agent, and forming a polymer layer by vapour phase polymerisation.

17. A device comprising a film obtained by the method according to claim 1.

18. The device according to claim 17, wherein the device is an organic electrochemical transistor, an electrochemical transducer, an electrochromic device, an electroluminescent device, an electroluminescent display, an organic capacitor, a supercapacitor, a sensor, a biosensor, an energy harvesting device, an antistatic material, a photovoltaic device, a storage device, an electrode, a touch screen, a circuit board, an antenna, a field effect transistor, a photodetector, or a thermoelectric device.

19. A system for manufacturing a patterned film on a surface of a substrate, the system comprising:
an oxidant unit configured to apply a solution comprising an oxidant on the surface, to form an oxidant layer on the surface;
means for drying the oxidant layer;
means for applying an inhibiting agent on the oxidant layer according to a pattern to at least partially inhibit polymerisation where the inhibiting agent is applied;and
a chamber configured to expose the surface to a monomer vapour at a polymerisation temperature of 20-95° C. under atmospheric pressure to form a polymer layer on non-patterned areas of the surface.
